(19) United States
(12) Patent Application Publication
(10) Pub. No.: US 2019/0096999 A1
(43) Pub. Date: Mar. 28, 2019

(54) SEMICONDUCTOR DEVICE AND METHOD OF MANUFACTURING SEMICONDUCTOR DEVICE

(71) Applicant: FUJI ELECTRIC CO., LTD., Kawasaki (JP)

(72) Inventor: Takahito KOJIMA, Matsumoto (JP)

(73) Assignee: FUJI ELECTRIC CO., LTD., Kawasaki (JP)

(21) Appl. No.: 16/199,508

(22) Filed: Nov. 26, 2018

Related U.S. Application Data
(63) Continuation of application No. PCT/JP2017/045405, filed on Dec. 18, 2017.

(30) Foreign Application Priority Data
Dec. 19, 2016 (JP) 2016-245155

(51) Int. Cl. H01L 29/16; H01L 29/78; H01L 29/10; H01L 29/08; H01L 29/417; H01L 29/423; H01L 29/66; H01L 21/04

(52) U.S. Cl. CPC H01L 29/1608; H01L 29/7813; H01L 29/1095; H01L 21/046; H01L 29/41741; H01L 29/4236; H01L 29/66734; H01L 29/0865

(57) ABSTRACT

A silicon carbide semiconductor device has an n⁺-type drift layer provided on a front surface of an n⁺-type silicon carbide substrate, a first p⁺-type region provided in a surface layer of the n⁺-type drift layer, and a trench formed on a front surface side of the n⁺-type silicon carbide substrate. The first p⁺-type region is constituted by a deep first p⁺-type region at a position deeper than a bottom of the trench, and a shallow first p⁺-type region at position shallower than the bottom of the trench. The deep first p⁺-type region is implanted with a first element at a predetermined ratio, the first element bonding with a second element that is displaced by an impurity that determines a conductivity type of the first p⁺-type region.

### CROSS REFERENCE TO RELATED APPLICATIONS

This is a continuation application of International Application PCT/JP2017/045405 filed on Dec. 18, 2017 which claims priority from a Japanese Patent Application No. 2016-245155 filed on Dec. 19, 2016, the contents of which are incorporated herein by reference.

### BACKGROUND

### 1. Field

Embodiments of the invention relate to a semiconductor device and a method of manufacturing a semiconductor device.

### 2. Description of Related Art

Conventionally, to reduce the ON resistance of an element in a power semiconductor device, a vertical metal oxide semiconductor field effect transistor (MOSFET) having a trench structure is fabricated (manufactured). In the vertical MOSFET, the trench structure in which a channel is formed orthogonal to a substrate surface enables the cell density per unit area to be increased more easily as compared to a planar structure in which the channel is formed parallel to the substrate surface. Therefore, with the trench structure, the current density per unit area may be increased more than with a planar structure and in terms of cost, this is advantageous.

Nonetheless, the vertical MOSFET having the trench structure has a structure in which an entire region of the inner wall of the trench is covered by a gate insulating film to form a channel in a vertical direction. A portion of the gate insulating film at a bottom of the trench is near a drain electrode and therefore, this portion of the gate insulating film is easily subjected to high electric field. In particular, since ultrahigh voltage elements are produced with a wide bandgap semiconductor material (semiconductor material having a wider bandgap than that of silicon such as silicon carbide (SiC)), adverse effects on the gate insulating film at the bottom of the trench significantly reduce reliability.

As a method to resolve such problems, a technique has been proposed of providing in a vertical MOSFET having a trench structure, a p⁺-type region parallel to and between the trenches (for example, refer to Japanese Laid-Open Patent Publication No. 2009-260253).

FIG. 9 is a cross-sectional view of a structure of a conventional vertical MOSFET. On a front surface of an n⁺-type silicon carbide substrate 101, an n-type drift layer 102 is deposited. On a surface of the n-type drift layer 102, on a side thereof opposite another side thereof toward the n⁺-type silicon carbide substrate 101, an n-type epitaxial layer 105 is provided. Further, in a surface layer of the n-type drift layer 102, on a first side thereof opposite a second side thereof toward the n⁺-type silicon carbide substrate 101, a first p⁺-type region 103 is selectively provided.

Further in the conventional vertical MOSFET, a p-type base layer 106, an n⁺-type source region 107, a p⁺⁺-type contact region 108, a gate insulating film 109, a gate electrode 1010, a rear electrode 1013, and a trench 1016 are further provided.

In the vertical MOSFET having the structure in FIG. 9, a pn junction of the first p⁺-type region 103 and the n-type epitaxial layer 105 is positioned deeper than the trench 1016 and therefore, electric field concentrates at a boundary of the first p⁺-type region 103 and the n-type epitaxial layer 105, enabling electric field concentration at a bottom of the trench 1016 to be mitigated.

### SUMMARY

According to an embodiment of the present invention, a semiconductor device includes a wide bandgap semiconductor substrate of a first conductivity type and containing a semiconductor material having a bandgap wider than that of silicon; a wide-bandgap semiconductor layer of the first conductivity type, provided on a front surface of the wide bandgap semiconductor substrate and containing a semiconductor material having a bandgap wider than that of silicon, the wide-bandgap semiconductor layer of the first conductivity type having an impurity concentration lower than that of the wide bandgap semiconductor substrate; a first base region of a second conductivity type, selectively provided in a surface layer on a first side of the wide-bandgap semiconductor layer of the first conductivity type, the first side of the wide-bandgap semiconductor layer of the first conductivity type being opposite a second side thereof toward the wide bandgap semiconductor substrate; a second base region of the second conductivity type selectively provided in the wide-bandgap semiconductor layer of the first conductivity type; a wide-bandgap semiconductor layer of the second conductivity type and containing a semiconductor material having a bandgap wider than that of silicon, the wide-bandgap semiconductor layer of the second conductivity type being provided on a surface of the wide-bandgap semiconductor layer of the first conductivity type, on the first side of the wide-bandgap semiconductor layer of the first conductivity type, opposite the second side thereof toward the wide bandgap semiconductor substrate; a source region of the first conductivity type, selectively provided in the wide-bandgap semiconductor layer of the second conductivity type; a trench penetrating the source region and the wide-bandgap semiconductor layer of the second conductivity type, and reaching the wide-bandgap semiconductor layer of the first conductivity type; a gate electrode provided in the trench, via a gate insulating film; a source electrode in contact with the wide-bandgap semiconductor layer of the second conductivity type and the source region; and a drain electrode provided on a rear surface of the wide bandgap semiconductor substrate. The first base region has a deep first base region at a position deeper toward the drain electrode than is a bottom of the trench and a shallow first base region at a position closer to the source region than is the bottom of the trench. The deep first base region is implanted with a first element at a predetermined ratio, the first element bonding with a second element that is displaced by an impurity that determines a conductivity type of the first base region.

In the embodiment, the shallow first base region is implanted with the first element at a predetermined ratio.

In the embodiment, the first element is carbon, when the impurity is an impurity that enters a silicon site, and

the first element is silicon, when the impurity is an impurity that enters a carbon site.

In the embodiment, the first element is carbon, when the impurity is aluminum.

According to an embodiment of the present invention, a method of manufacturing a semiconductor device, includes forming a wide-bandgap semiconductor layer of a first conductivity type on a front surface of a wide bandgap semiconductor substrate of the first conductivity type and containing a semiconductor material having a bandgap wider than that of silicon, the wide-bandgap semiconductor layer of the first conductivity type containing a semiconductor material having a bandgap wider than that of silicon, the wide-bandgap semiconductor layer of the first conductivity type having an impurity concentration lower than that of the wide bandgap semiconductor substrate; selectively forming a first base region of a second conductivity type in a surface layer of the wide-bandgap semiconductor layer of the first conductivity type; selectively forming a second base region of the second conductivity type in the wide-bandgap semiconductor layer of the first conductivity type; forming a wide-bandgap semiconductor layer of the second conductivity type on a surface of the wide-bandgap semiconductor layer of the first conductivity type, the wide-bandgap semiconductor layer of the second conductivity type containing a semiconductor material having a bandgap wider than that of silicon; selectively forming a source region of the first conductivity type in the wide-bandgap semiconductor layer of the second conductivity type; forming a trench that penetrates the source region and the wide-bandgap semiconductor layer of the second conductivity type, and that reaches the wide-bandgap semiconductor layer of the first conductivity type; forming a gate electrode in the trench, via a gate insulating film; forming a source electrode in contact with the source region and the wide-bandgap semiconductor layer of the second conductivity type; and forming a drain electrode at a rear surface of the wide bandgap semiconductor substrate. Forming the first base region includes implanting a deep first base region in the first base region at a position deeper toward the drain electrode than is a bottom of the trench, with both an impurity that determines a conductivity type of the first base region and a first element that bonds with a second element that is displaced by the impurity.

In the embodiment, selectively forming the first base region includes implanting a shallow first base region in the first base region at a position closer to the source region than is the bottom of the trench, with both the impurity and the first element.

Objects, features, and advantages of the present invention are specifically set forth in or will become apparent from the following detailed description of the invention when read in conjunction with the accompanying drawings.

### BRIEF DESCRIPTION OF THE DRAWINGS

FIG. 1 is a cross-sectional view of a silicon carbide semiconductor device according to an embodiment;

FIG. 2 is a graph depicting resistance and leak current with respect to drain voltage at regions of the silicon carbide semiconductor device according to the embodiment;

FIG. 3 is a cross-sectional view (part 1) schematically depicting the silicon carbide semiconductor device according to the embodiment during manufacture;

FIG. 4 is a cross-sectional view (part 2) schematically depicting the silicon carbide semiconductor device according to the embodiment during manufacture;

FIG. 5 is a cross-sectional view (part 3) schematically depicting the silicon carbide semiconductor device according to the embodiment during manufacture;

FIG. 6 is a cross-sectional view (part 4) schematically depicting the silicon carbide semiconductor device according to the embodiment during manufacture;

FIG. 7 is a cross-sectional view (part 5) schematically depicting the silicon carbide semiconductor device according to the embodiment during manufacture;

FIG. 8 is a cross-sectional view (part 6) schematically depicting the silicon carbide semiconductor device according to the embodiment during manufacture;

FIG. 9 is a cross-sectional view of a structure of a conventional vertical MOSFET; and

FIG. 10 is a graph depicting high voltage leak in a conventional trench-type silicon carbide semiconductor device.

### DESCRIPTION OF EMBODIMENTS

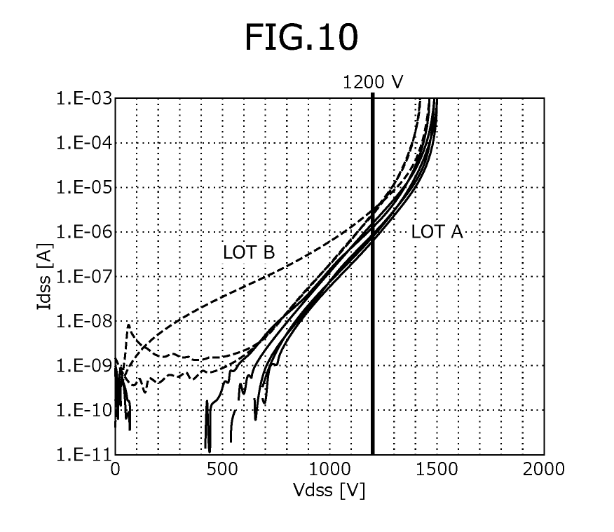

First, problems associated with the related techniques will be discussed. In a conventional trench-type silicon carbide semiconductor device, due to leak current that is between a drain and a source and that increases dependent on voltage, a large leak current is generated in a high voltage region. FIG. 10 is a graph depicting high voltage leak in the conventional trench-type silicon carbide semiconductor device. In FIG. 10, a vertical axis represents drain saturation current in units of A, while a horizontal axis represents voltage between the drain and the source in units of V. As depicted in FIG. 10, in the semiconductor device, at a high voltage, a leak current of about 1 μA is generated.

Embodiments of a semiconductor device and a method of manufacturing a semiconductor device according to the present invention will be described in detail with reference to the accompanying drawings. In the present description and accompanying drawings, layers and regions prefixed with n or p mean that majority carriers are electrons or holes. Additionally, + or − appended to n or p means that the impurity concentration is higher or lower, respectively, than layers and regions without + or −. Cases where symbols such as n's and p's that include + or − are the same indicate that concentrations are close and therefore, the concentrations are not necessarily equal. In the description of the embodiments below and the accompanying drawings, main portions that are identical will be given the same reference numerals and will not be repeatedly described. Further, in the present description, when Miller indices are described, “−” means a bar added to an index immediately after the “−”, and a negative index is expressed by prefixing “−” to the index.

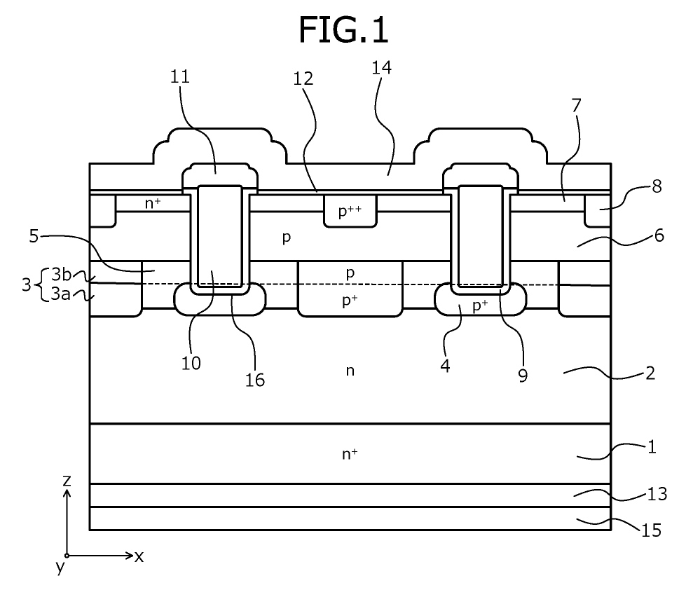

FIG. 1 is a cross-sectional view of a silicon carbide semiconductor device according to an embodiment. As depicted in FIG. 1, in the silicon carbide semiconductor device according to the embodiment, an n-type drift layer (first wide-bandgap semiconductor layer of the first conductivity type) 2 is deposited on a first main surface (front surface), e.g., a (0001) plane (Si-face) of an n⁺-type silicon carbide substrate (wide bandgap semiconductor substrate of the first conductivity type) 1.

The n⁺-type silicon carbide substrate 1 is a silicon carbide single-crystal substrate. The n-type drift layer 2 is, for example, a low-concentration n-type drift layer having an impurity concentration that is lower than that of the n⁺-type silicon carbide substrate 1. On a surface of the n-type drift layer 2, on the first side thereof opposite the second side thereof toward the n⁺-type silicon carbide substrate 1, an n-type epitaxial layer 5 is provided. The n-type epitaxial layer 5 is a high-concentration n-type drift layer having an impurity concentration lower than that of the n⁺-type silicon carbide substrate 1 and higher than that of the n-type drift layer 2.

On the surface side of the n-type drift layer 2, on the first side thereof opposite the second side toward the n⁺-type silicon carbide substrate 1, a p-type base layer (wide-bandgap semiconductor layer of a second conductivity type) 6 is provided. The p-type base layer 6 is in contact with a first p⁺-type region 3 described hereinafter. Hereinafter, the n⁺-type silicon carbide substrate 1, the n-type drift layer 2, and the p-type base layer 6 collectively constitute a silicon carbide semiconductor base.

At a second main surface (rear surface, i.e., rear surface of the silicon carbide semiconductor base) of the n⁺-type silicon carbide substrate 1, a rear electrode (drain electrode) 13 is provided. The rear electrode 13 constitutes the drain electrode. On a surface of the rear electrode 13, a drain electrode pad 15 is provided.

At a first main surface side (a p-type base layer 6 side) of the silicon carbide semiconductor base, a trench structure is formed. In particular, from a surface of the p-type base layer 6, on a first side (a first main surface side of the silicon carbide semiconductor base) thereof opposite a second side thereof toward the n⁺-type silicon carbide substrate 1, a trench 16 penetrates the p-type base layer 6 and reaches the n-type epitaxial layer 5. Along an inner wall of the trench 16, a gate insulating film 9 is formed at a side wall and a bottom of the trench 16, and a gate electrode 10 is formed on the gate insulating film 9 in the trench 16. The gate electrode 10 is insulated from the n-type drift layer 2 and the p-type base layer 6 by the gate insulating film 9. A part of the gate electrode 10 may protrude from a top (side where a source electrode pad 14 is provided) of the trench 16, toward the source electrode pad 14.

At the surface of the n-type drift layer 2, on the first side (the first main surface side of the silicon carbide semiconductor base) thereof opposite the second side thereof toward the n⁺-type silicon carbide substrate 1, the first p⁺-type region (first base region of the second conductivity type) 3 and a second p⁺-type region (second base region of the second conductivity type) 4 are selectively provided. A lower end part (drain-side end part) of the first p⁺-type region 3 is positioned further on a drain side than is the bottom of the trench 16. The first p⁺-type region 3 is constituted by a deep first p⁺-type base region (deep first base region) 3a at a deep position further on the drain side (negative direction of a z axis) than is the bottom of the trench 16 and a shallow first p⁺-type base region (shallow first base region) 3b at a close position further on a source side (positive direction of the z axis) than is the bottom of the trench 16. A lower end part of the second p⁺-type base region 4 is positioned further on the drain side than is the bottom of the trench 16. The second p⁺-type base region 4 is formed at a position opposing the bottom of the trench 16 in a depth direction. A width of the second p⁺-type base region 4 is wider than a width of the trench 16. The bottom of the trench 16 may reach the second p⁺-type base region 4, or may be positioned in the n-type epitaxial layer 5 sandwiched between the p-type base layer 6 and the second p⁺-type base region 4 and needs not be in contact with the second p⁺-type base region 4.

Provision of the deep first p⁺-type base region 3a and the second p⁺-type region 4 enables a pn junction of the deep first p⁺-type base region 3a and the n-type epitaxial layer 5, and a pn junction of the second p⁺-type base region 4 and the n-type epitaxial layer 5 to be formed at a position close to the bottom of the trench 16 in the depth direction (the negative direction of the z axis). In this manner, the pn junctions are formed, enabling application of high electric field to the gate insulating film 9 at the bottom of the trench 16 to be prevented. Therefore, even when a wide bandgap semiconductor material is used as a semiconductor material, a high breakdown voltage is possible. Further, the second p⁺-type base region 4 having a width that is wider than the trench width is provided, enabling electric field to be mitigated at a corner part of the bottom of the trench 16 where electric field concentrates, thereby further enabling the breakdown voltage to be increased.

In FIG. 1, while only two trench MOS structures are depicted, further MOS gate (insulated gate constituted by a metal oxide film semiconductor) structures having a trench structure may be disposed in parallel.

Here, to reduce leak current of the silicon carbide semiconductor device, the inventors simulated changes of leak current while varying the lifetime (amount of defects) of each region of the silicon carbide semiconductor device.

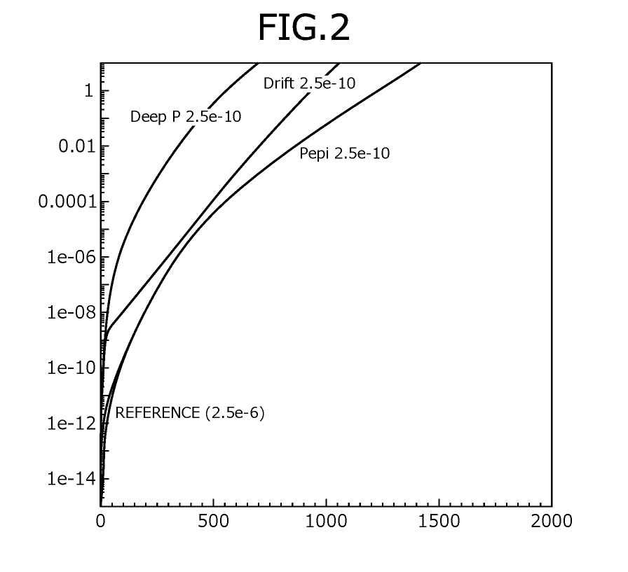

FIG. 2 is a graph depicting resistance and leak current with respect to drain voltage at the regions of the silicon carbide semiconductor device according to the embodiment. In FIG. 2, at the n-type drift layer 2, the first p⁺-type region 3 and the p-type base layer 6, the amount of defects was set to be 2.5×10⁻⁶/cm³ and 2.5×10⁻¹⁰/cm³ for each, and the leak current was simulated.

In FIG. 2, a horizontal axis represents drain voltage in units of V, while a vertical axis represents leak current in units of μA. Further, a reference curve indicates simulation results in a case where the amount of defects of the n-type drift layer 2, the first p⁺-type region 3 and the p-type base layer 6 was 2.5×10⁻⁶/cm³. A Pepi curve indicates simulation results in a case where the amount of defects of the p-type base layer 6 was 2.5×10⁻¹⁰/cm³ and a Drift curve indicates simulation results in a case where the amount of defects of the n-type drift layer 2 was 2.5×10⁻¹⁰/cm³. A Deep P curve indicates simulation results in a case where the amount of defects of the first p⁺-type region 3 was 2.5×10⁻¹⁰/cm³. From the results, it is found that when the amount of defects of the first p⁺-type region 3 is large, the leak current increases.

There is a report indicating that defects of the first p⁺-type region 3 are formed by ion implantation for forming the first p⁺-type region 3 (for example, refer to Takeshi Mitani, et al, “Depth Profiling of Ion-Implantation Damage in SiC Crystals by Cathodoluminescence Spectroscopy”, (USA), Materials Science Forum, Vols. 600-603(2009), pp. 615-618).

The first p⁺-type region 3 is formed by ion implantation of a p-type impurity, e.g., aluminum (Al). Aluminum is an element that enters a silicon site by ion implantation and thus, aluminum is located close to silicon in a crystal of silicon carbide. Thus, silicon (Si) is displaced by aluminum and the displaced silicon becomes a defect.

In the silicon carbide semiconductor device of the embodiment, the first p⁺-type region 3 is two-layered, including a deep first p⁺-type region 3a and a shallow first p⁺-type region 3b. In the first p⁺-type region 3, a part of a pn junction between the deep first p⁺-type region 3a and the n-type epitaxial layer 5 is a part that is most effective in increasing the breakdown voltage. Therefore, by suppressing the leak current due to the defects of the deep first p⁺-type region 3a, decrease of the breakdown voltage may be effectively prevented.

To reduce the defects of the deep first p⁺-type region 3a, in the embodiment, an element, for example, carbon (C), corresponding to a p-type impurity is implanted at a predetermined ratio. As a result, the implanted carbon and the displaced silicon bond and crystallize with silicon carbide, preventing the silicon from becoming a defect. Here, the predetermined ratio is an amount necessary for bonding with the silicon displaced by the implantation of aluminum. In particular, a doping amount (Dc) of carbon is an amount satisfying 0.7≤D_{C}/D_{Al}≤1.3 with respect to a doping amount (D_{Al}) of aluminum.

Further, the first p⁺-type region 3 may be formed by ion implanting a p-type impurity other than aluminum, for example, boron (B). In this case, an element corresponding to the p-type impurity is implanted in the deep first p⁺-type region 3a at a predetermined ratio. For example, when the p-type impurity is an element that enters a silicon site, the element corresponding to the p-type impurity is carbon, and like aluminum, carbon is implanted in the deep first p⁺-type region 3a at a predetermined ratio. On the other hand, when the p-type impurity is an element that enters a carbon site, the element corresponding to the p-type impurity is silicon, and conversely to aluminum, silicon is implanted in the deep first p⁺-type region 3a, at a predetermined ratio. As a result, carbon displaced by the p-type impurity and the implanted silicon bond and crystallize with silicon carbide, preventing the carbon from becoming a defect.

The element corresponding to the p-type impurity may be further implanted in the shallow first p⁺-type region 3b at a predetermined ratio. Similar to the case of the deep first p⁺-type region 3a, when the p-type impurity is an element that enters a silicon site, carbon is implanted at a predetermined ratio and when the p-type impurity is an element that enters a carbon site, silicon is implanted at a predetermined ratio.

Further, in the embodiment, while the case of the n⁺-type silicon carbide substrate 1 has been described, similarly, in a case of a p⁺-type silicon carbide substrate, defects may be prevented. In this case, the first p⁺-type region 3 is an n-type first n⁺-type region, and the deep first p⁺-type region 3a is an n-type deep first n⁺-type region. For example, when an impurity of the first n⁺-type region is nitrogen, since nitrogen is an element that enters a carbon site, silicon is implanted at a predetermined ratio. Further, when an impurity of the first n⁺-type region is phosphorus (p), since phosphorus is an element that enters a silicon site, carbon is implanted at a predetermined ratio.

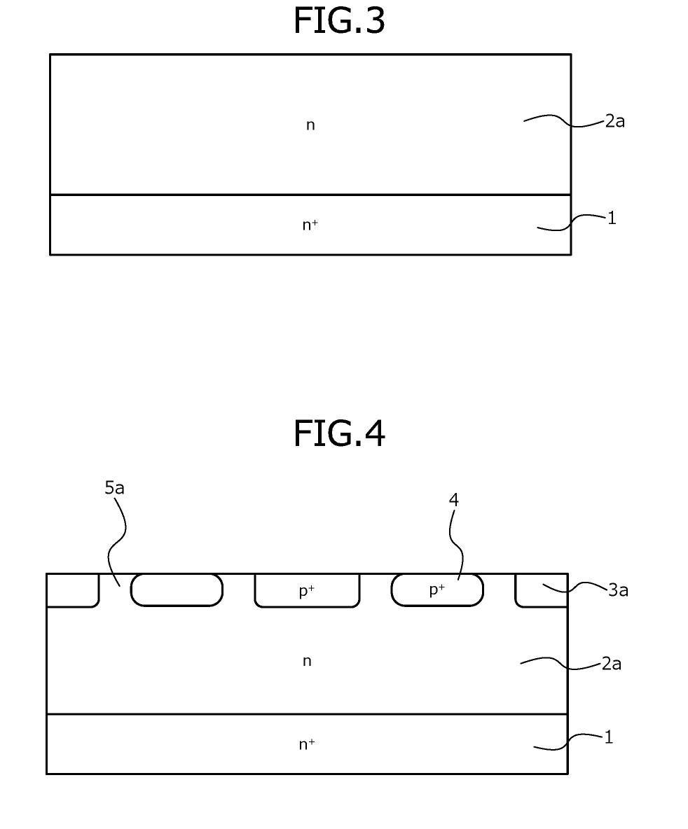

Next, a method of manufacturing a silicon carbide semiconductor device according to the embodiment will be described. FIGS. 3, 4, 5, 6, 7, and 8 are cross-sectional views schematically depicting the silicon carbide semiconductor device according to the embodiment during manufacture.

First, the n⁺-type silicon carbide substrate 1 made of an n-type silicon carbide is prepared. Subsequently, on the first main surface of the n⁺-type silicon carbide substrate 1, while an n-type impurity, e.g., nitrogen atoms (N), is doped, a first n-type drift layer (first wide-bandgap semiconductor layer of the first conductivity type) 2a made of silicon carbide is formed by epitaxial growth to have a thickness of, for example, about 30 μm. The first n-type drift layer 2a becomes the n-type drift layer 2. The state up to here is depicted in FIG. 3.

Next, on a surface of the first n-type drift layer 2a, a non-depicted mask having desired openings is formed by a photolithographic technique using, for example, an oxide film. Subsequently, by an ion implantation method using the oxide film as a mask, a p-type impurity, e.g., aluminum atoms, and an element corresponding to the p-type impurity, e.g., carbon, which corresponds to the aluminum atoms, are implanted together. As a result, in a part of a surface region of the first n-type drift layer 2a, for example, the second p⁺-type region (second base region of the second conductivity type) 4 and the deep first p⁺-type region (first base region of the second conductivity type) 3a at a depth of about 0.5 μm are formed so that, for example, a distance between the deep first p⁺-type region 3a and the second p⁺-type base region 4 that are adjacent to each other is about 1.0 μm.

Here, while the element that corresponds to the p-type impurity is also implanted in the second p⁺-type base region 4, this poses no particular problem. Further, when implanted together, the p-type impurity is ion implanted, and using the same mask, the element corresponding to the p-type impurity is successively ion implanted. Further, conversely, when implanted together, the element corresponding to the p-type impurity is ion implanted, and using the same mask, the p-type impurity may be successively ion implanted. Dose amounts of the ion implantation for forming the deep first p⁺-type region 3a and the second p⁺-type base region 4 may be set, for example, so that the impurity concentration thereof becomes about 5×10¹⁸/cm³. Next, the mask used in the ion implantation for forming the deep first p⁺-type region 3a and the second p⁺-type base region 4 is removed. Subsequently, by an ion implantation method, an n-type impurity, e.g., nitrogen atoms, is ion implanted. As a result, between the deep first p⁺-type region 3a and the second p⁺-type base region 4 of the surface layer of the first n-type drift layer 2a, for example, a first n-type epitaxial layer 5a at a depth of about 0.5 μm or less is formed. A dose amount during ion implantation for forming the first n-type epitaxial layer 5a, for example, may be set so that an impurity concentration thereof becomes about 1×10¹⁷/cm³. The state up to here is depicted in FIG. 4.

Next, on the surface of the first n-type drift layer 2a, while an n-type impurity, e.g., nitrogen atoms is doped, a second n-type drift layer (second wide-bandgap semiconductor layer of the first conductivity type) 2b, for example, is formed by epitaxial growth to have a thickness of about 0.5 μm. The second n-type drift layer 2b and the first n-type drift layer 2a collectively constitute the n-type drift layer 2. Conditions of the epitaxial growth for forming the second n-type drift layer 2b, for example, may be set so that an impurity concentration of the second n-type drift layer 2b becomes about 3×10¹⁵/cm³.

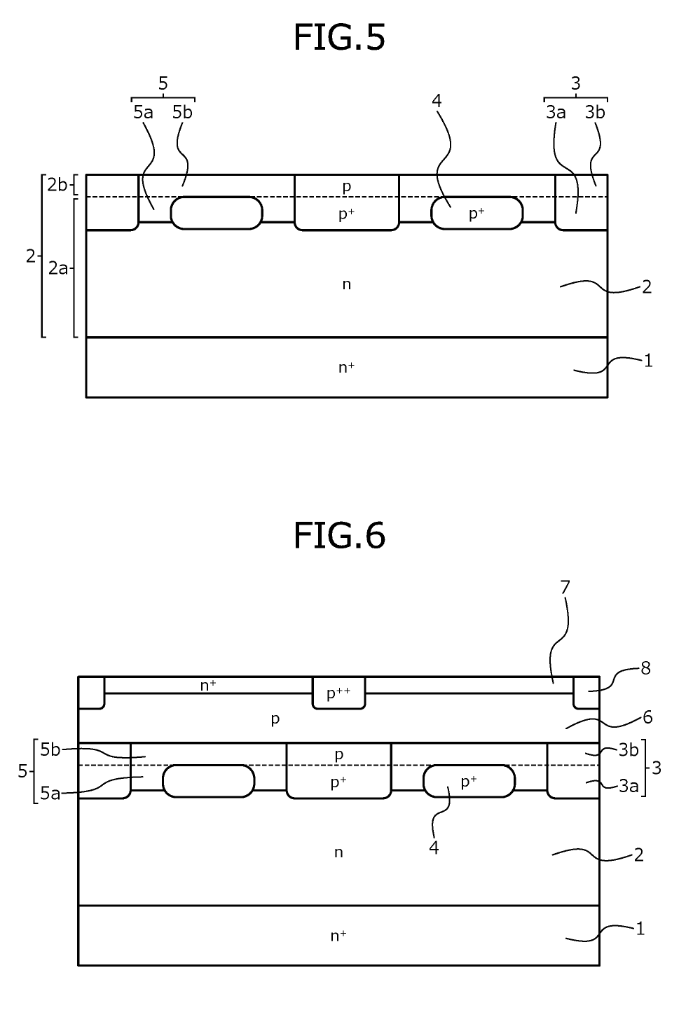

Next, on the surface of the n-type drift layer 2, a non-depicted mask having desired openings is formed by a photolithographic technique using, for example, an oxide film. Subsequently, by an ion implantation method using the oxide film as a mask, a p-type impurity, e.g., aluminum atoms, is ion implanted. Here, the p-type impurity, e.g., aluminum atoms, and an element corresponding to the p-type impurity, e.g., carbon, which corresponds to the aluminum atoms, may be implanted together. As a result, in a part of a surface region of the n-type drift layer 2, for example, the shallow first p⁺-type region (first base region of the second conductivity type) 3b at a depth of about 0.5 μm is formed, for example, so as to overlap a top part of the deep first p⁺-type region 3a. The shallow first p⁺-type region 3b and the deep first p⁺-type region 3a collectively constitute the first p⁺-type base region 3. A dose amount of the ion implantation for forming the shallow first p⁺-type region 3b, for example, may be set so that an impurity concentration thereof becomes about 5.0×10¹⁸/cm³. Next, the mask used in the ion implantation for forming the shallow first p⁺-type region 3b is removed. Subsequently, by ion implantation, an n-type impurity, e.g., nitrogen atoms, is ion implanted. As a result, in a part of a surface layer of the second n-type drift layer 2b, for example, a second n-type epitaxial layer (second region of the first conductivity type) 5b at a depth of about 0.5 μm is formed so as to contact the deep first p⁺-type region 3a, the second p⁺-type base region 4, and the first n-type epitaxial layer 5a. A dose amount of the ion implantation for providing the second n-type epitaxial layer 5b, for example, may be set so that an impurity concentration thereof becomes about 1×10¹⁷/cm³. The second n-type epitaxial layer 5b and the first n-type epitaxial layer 5a collectively constitute the n-type epitaxial layer 5. The state up to here is depicted in FIG. 5.

Next, on the surface (i.e., surfaces of the first p⁺-type region 3 and the second n-type epitaxial layer 5b) of the n-type drift layer 2, while a p-type impurity, e.g., aluminum atoms, is doped, the p-type base layer (wide-bandgap semiconductor layer of the second conductivity type) 6, for example, is formed by epitaxial growth to have a thickness of about 0.9 to 1.3 μm. Conditions of the epitaxial growth for forming the p-type base layer 6, for example, may be set so that an impurity concentration thereof becomes about 2×10¹⁷/cm³, which is equal to or less than the impurity concentration of the first p⁺-type base region 3. By the processes up to here, the silicon carbide semiconductor base in which the n-type drift layer 2 and the p-type base layer 6 are stacked on the n⁺-type silicon carbide substrate 1 is formed.

Next, on a surface of the p-type base layer 6, a non-depicted mask having desired openings is formed by a photolithographic technique using, for example, an oxide film. Subsequently, by an ion implantation method using the oxide film as a mask, an n-type impurity, e.g., phosphorus, is ion implanted. As a result, in part of a surface layer of the p-type base layer 6, an n⁺-type source region (source region of the first conductivity type) 7 is formed. A dose amount of the ion implantation for forming the n⁺-type source region 7, for example, may be set so that an impurity concentration thereof becomes higher than that of the first p⁺-type region 3. Next, the mask used in the ion implantation for forming the n⁺-type source region 7 is removed. Subsequently, on the surface of the p-type base layer 6, a non-depicted mask having desired openings is formed by a photolithographic technique using, for example, an oxide film, and using the oxide film as a mask, a p-type impurity, e.g., aluminum, is ion implanted in the surface of the p-type base layer 6. As a result, in a part of a surface region of the p-type base layer 6, a p⁺⁺-type contact region 8 is formed. A dose amount of the ion implantation form forming the p⁺⁺-type contact region 8, for example, may be set so that an impurity concentration thereof becomes higher than that of the second p⁺-type region 4. Subsequently, the mask used in the ion implantation for forming the p⁺⁺-type contact region 8 is removed. The sequence of the ion implantation for forming the n⁺-type source region 7 and the ion implantation for forming the p⁺⁺-type contact region 8 may be interchanged. The state up to here is depicted in FIG. 6.

Next, heat treatment (annealing) is performed, for example, activating the deep first p⁺-type region 3a, the shallow first p⁺-type region 3b, the n⁺-type source region 7, and the p⁺⁺-type contact region 8. A temperature of the heat treatment, for example, may be about 1700 degrees C. A period of the heat treatment, for example, may be about 2 minutes. As described, ion implanted regions may be collectively activated by one session of heat treatment, or activation may be performed by performing the heat treatment each time ion implantation is performed.

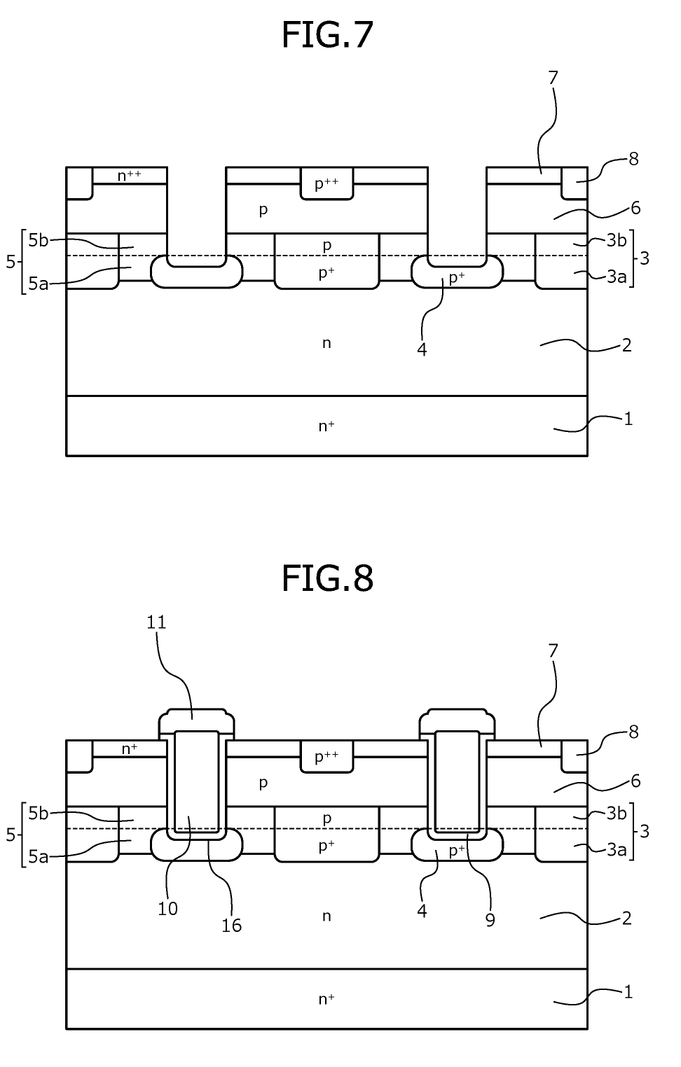

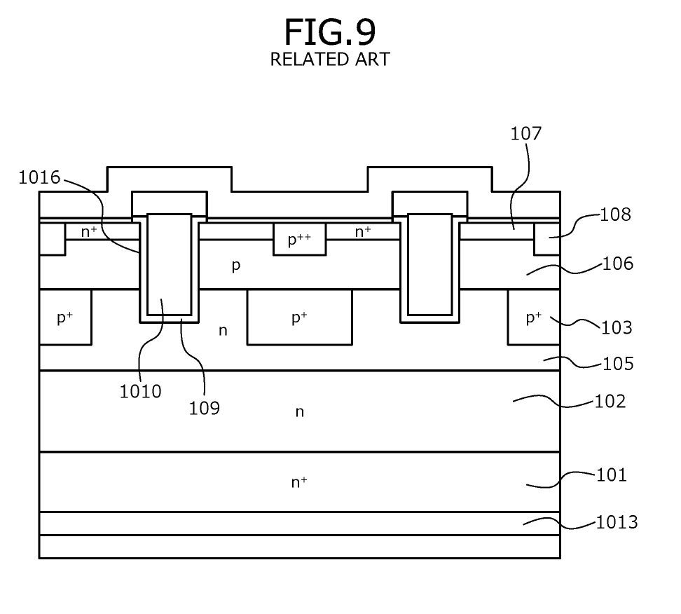

Next, on the surface (i.e., surfaces of the n⁺-type source region 7 and the p⁺⁺-type contact region 8) of the p-type base layer 6, a non-depicted mask having desired openings is formed by a photolithographic technique using, for example, an oxide film. Subsequently, by dry etching or the like using the oxide film as a mask, the trench 16 is formed penetrating the n⁺-type source region 7 and the p-type base layer 6, and reaching the n-type epitaxial layer 5. The bottom of the trench 16 may reach the second p⁺-type region 4, or may positioned in the n-type epitaxial layer 5, sandwiched between the p-type base layer 6 and the second p⁺-type region 4. Subsequently, the mask for forming the trench 16 is removed. The state up to here is depicted in FIG. 7.

Next, the gate insulating film 9 is formed along surfaces of the n⁺-type source regions 7 and the p⁺⁺-type contact regions 8, and along the side walls and bottoms of the trenches 16. The gate insulating film 9 may be formed by heat treatment at a temperature of about 1000 degrees C. in an oxygen atmosphere. Further, the gate insulating film 9 may be formed by a deposition method by a chemical reaction such as that for a high temperature oxide (HTO), etc.

Next, on the gate insulating film 9, a polycrystalline silicon layer doped with, for example, phosphorus, is formed. The polycrystalline silicon layer is formed so as to be embedded in the trenches 16. The polycrystalline silicon layer is patterned and left inside the trenches 16, whereby the gate electrode 10 is formed. A part of the gate electrode 10 may protrude from the top (the source electrode pad 14 side) of the trench 16 toward the source electrode pad 14.

Next, for example, a phosphate glass is formed so as to cover the gate insulating film 9 and the gate electrode 10, and have a thickness of about 1 μm, forming an interlayer insulating film 11. The interlayer insulating film 11 and the gate insulating film 9 are patterned and selectively removed, thereby forming a contact hole and exposing the n⁺-type source region 7 and the p⁺⁺-type contact region 8. Thereafter, heat treatment (reflow) is performed, planarizing the interlayer insulating film 11. The state up to here is depicted in FIG. 8.

Subsequently, in the contact hole and on the interlayer insulating film 11, a conductive film constituting a source electrode 12 is formed. The conductive film is selectively removed, for example, leaving the source electrode 12 only in the contact hole.

Subsequently, on the second main surface of the n⁺-type silicon carbide substrate 1, the drain electrode 13 is formed by, for example, a nickel (Ni) film. Thereafter, for example, heat treatment at a temperature of about 970 degrees C. is performed, forming an ohmic junction between the n⁺-type silicon carbide substrate 1 and the drain electrode 13.

Next, for example, by a sputtering method, for example, an aluminum film is provided so as to cover the source electrode 12 and the interlayer insulating film 11, and have a thickness of, for example, about 5 μm. Thereafter, the aluminum film is selectively removed so as to remain covering an active region of the device overall, thereby forming the source electrode pad 14.

Next, on a surface of the drain electrode 13, for example, titanium (Ti), nickel and gold (Au) are sequentially layered, whereby the drain electrode pad 15 is formed. Thus, semiconductor device depicted in FIG. 1 is completed.

As described above, according to the silicon carbide semiconductor device according to the embodiment, in the deep first p⁺-type region, an element that corresponds to a p-type impurity is implanted at a predetermined ratio. As a result, an element displaced by the p-type impurity may bond with the element that corresponds to the p-type impurity, and may crystallize with the silicon carbide. As a result, formation of defects by the element displaced by the p-type impurity may be reduced. Therefore, the silicon carbide semiconductor device according to the embodiment suppresses high voltage leaks.

Further, the element corresponding to the p-type impurity may be further implanted in the shallow first p⁺-type region, at a predetermined ratio. In this case, in the shallow first p⁺-type region as well, the formation of defects by the element displaced by the p-type impurity may be reduced. Therefore, the silicon carbide semiconductor device according to the embodiment may further suppress high voltage leaks.

In the silicon carbide semiconductor device according to the embodiment, the impurity concentration of the first p⁺-type region does not vary from an existing silicon carbide semiconductor device. Therefore, the first p⁺-type region may have a function to increase the breakdown voltage and mitigate the high electric field applied to the gate insulating film, and a function to efficiently migrate to the source electrode, hole current generated when avalanche breakdown occurs.

In the foregoing, regarding the present invention, while a case has been described in which the first main surface of a silicon carbide substrate containing silicon carbide is a (0001) plane and on the (0001) plane, a MOS gate structure is configured, without limitation hereto, various modifications are possible such as regarding the type (e.g., gallium nitride (GaN), etc.) of wide bandgap semiconductor material, orientation of the substrate main surface, etc. Further, in the present invention, in the embodiments, while the first conductivity type is assumed to be an n-type and the second conductivity type is assumed to be a p-type, the present invention is similarly implemented when the first conductivity type is a p-type and the second conductivity type is an n-type.

According to the described invention, in the deep first p⁺-type region, an element that corresponds to the p-type impurity is implanted at a predetermined ratio. As a result, an element that is displaced by the p-type impurity bonds with the element that corresponds to the p-type impurity, and may be crystallized with silicon carbide. As a result, formation of defects by the element that is displaced by the p-type impurity may be reduced. Therefore, the semiconductor device of the present invention suppresses high voltage leaks.

Further, in the shallow first p⁺-type region, an element that corresponds to the p-type impurity may be implanted at a predetermined ratio. In this case, in the shallow first p⁺-type region as well, the formation of defects by the element displaced by the p-type impurity may be reduced. Therefore, the semiconductor device of the present invention may further suppress high voltage leaks.

The semiconductor device and the method of manufacturing a semiconductor device according to the present invention achieve an effect in that high voltage leaks may be suppressed.

As described, the semiconductor substrate according to the present invention is useful for a semiconductor substrate of a high-voltage semiconductor device used in power converting equipment, and in power supply devices such as in various industrial machines.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

What is claimed is:

1. A semiconductor device comprising:
a wide bandgap semiconductor substrate of a first conductivity type and containing a semiconductor material having a bandgap wider than that of silicon;
a wide-bandgap semiconductor layer of the first conductivity type, provided on a front surface of the wide bandgap semiconductor substrate and containing a semiconductor material having a bandgap wider than that of silicon, the wide-bandgap semiconductor layer of the first conductivity type having an impurity concentration lower than that of the wide bandgap semiconductor substrate;
a first base region of a second conductivity type, selectively provided in a surface layer on a first side of the wide-bandgap semiconductor layer of the first conductivity type, the first side of the wide-bandgap semiconductor layer of the first conductivity type being opposite a second side thereof toward the wide bandgap semiconductor substrate;
a second base region of the second conductivity type selectively provided in the wide-bandgap semiconductor layer of the first conductivity type;
a wide-bandgap semiconductor layer of the second conductivity type and containing a semiconductor material having a bandgap wider than that of silicon, the wide-bandgap semiconductor layer of the second conductivity type being provided on a surface of the wide-bandgap semiconductor layer of the first conductivity type, on the first side of the wide-bandgap semiconductor layer of the first conductivity type, opposite the second side thereof toward the wide bandgap semiconductor substrate;
a source region of the first conductivity type, selectively provided in the wide-bandgap semiconductor layer of the second conductivity type;
a trench penetrating the source region and the wide-bandgap semiconductor layer of the second conductivity type, and reaching the wide-bandgap semiconductor layer of the first conductivity type;
a gate electrode provided in the trench, via a gate insulating film;
a source electrode in contact with the wide-bandgap semiconductor layer of the second conductivity type and the source region; and
a drain electrode provided on a rear surface of the wide bandgap semiconductor substrate, wherein
the first base region has a deep first base region at a position deeper toward the drain electrode than is a bottom of the trench and a shallow first base region at a position closer to the source region than is the bottom of the trench, and
the deep first base region is implanted with a first element at a predetermined ratio, the first element bonding with a second element that is displaced by an impurity that determines a conductivity type of the first base region.

2. The semiconductor device according to claim 1, wherein
the shallow first base region is implanted with the first element at a predetermined ratio.

3. The semiconductor device according to claim 1, wherein
the first element is carbon, when the impurity is an impurity that enters a silicon site, and
the first element is silicon, when the impurity is an impurity that enters a carbon site.

4. The semiconductor device according to claim 1, wherein
the first element is carbon, when the impurity is aluminum.

5. A method of manufacturing a semiconductor device, the method comprising:
forming a wide-bandgap semiconductor layer of a first conductivity type on a front surface of a wide bandgap semiconductor substrate of the first conductivity type and containing a semiconductor material having a bandgap wider than that of silicon, the wide-bandgap semiconductor layer of the first conductivity type containing a semiconductor material having a bandgap wider than that of silicon, the wide-bandgap semiconductor layer of the first conductivity type having an impurity concentration lower than that of the wide bandgap semiconductor substrate;
selectively forming a first base region of a second conductivity type in a surface layer of the wide-bandgap semiconductor layer of the first conductivity type;
selectively forming a second base region of the second conductivity type in the wide-bandgap semiconductor layer of the first conductivity type;
forming a wide-bandgap semiconductor layer of the second conductivity type on a surface of the wide-bandgap semiconductor layer of the first conductivity type, the wide-bandgap semiconductor layer of the second conductivity type containing a semiconductor material having a bandgap wider than that of silicon;
selectively forming a source region of the first conductivity type in the wide-bandgap semiconductor layer of the second conductivity type;
forming a trench that penetrates the source region and the wide-bandgap semiconductor layer of the second conductivity type, and that reaches the wide-bandgap semiconductor layer of the first conductivity type;
forming a gate electrode in the trench, via a gate insulating film;
forming a source electrode in contact with the source region and the wide-bandgap semiconductor layer of the second conductivity type; and
forming a drain electrode at a rear surface of the wide bandgap semiconductor substrate, wherein
selectively forming the first base region includes implanting a deep first base region in the first base region at a position deeper toward the drain electrode than is a bottom of the trench, with both an impurity that determines a conductivity type of the first base region and a first element that bonds with a second element that is displaced by the impurity.

6. The method according to claim 5, wherein
selectively forming the first base region includes implanting a shallow first base region in the first base region at a position closer to the source region than is the bottom of the trench, with both the impurity and the first element.
